(19) United States
(12) Patent Application Publication
(10) Pub. No.: US 2011/0204496 A1
(43) Pub. Date: Aug. 25, 2011

(54) CIRCUIT MODULE, ELECTRONIC DEVICE INCLUDING THE SAME, AND CIRCUIT MODULE MANUFACTURING METHOD

(76) Inventors: Shinpei KUBOTA, Osaka (JP); Makoto YAMAMOTO, Osaka (JP)

(21) Appl. No.: 12/946,172

(22) Filed: Nov. 15, 2010

(30) Foreign Application Priority Data
Feb. 25, 2010 (JP) 2010-039591

(51) Int. Cl. H01L 23/52; H01L 21/50

(52) U.S. Cl. 257/659; 438/121; 257/E23.141; 257/E21.499

(57) ABSTRACT

Provided is a circuit module reduced in size. The circuit module includes: a substrate to which electronic parts are mounted; a shield case; and a bonding material for bonding the substrate and the shield case. The shield case includes legs extending from given side walls of the shield case to overlap with portions of the side faces of the substrate, and the portions of the side faces of the substrate are bonded to the legs of the shield case by the bonding material. The shield case includes openings formed in the given side walls of the shield case to expose overlapping portions where the portions of the side faces of the substrate overlap with the legs of the shield case.

This application is based on Japanese Patent Application No. 2010-039591 filed on Feb. 25, 2010, the contents of which are hereby incorporated by reference.

### BACKGROUND OF THE INVENTION

1. Field of the Invention

The present invention relates to a circuit module, an electronic device that includes the circuit module, and a method of manufacturing the circuit module.

2. Description of Related Art

There have been known circuit modules in which an IC and other electronic parts are mounted to a substrate and a shield case covers the electronic parts mounted to the substrate. An example of those circuit modules is disclosed in JP 2003-168901 A. A structural example of a conventional circuit module is briefly described below with reference to FIG. 9.

As illustrated in FIG. 9, the conventional circuit module includes a substrate 101 whose outer shape is substantially quadrangular in plan view, and an IC and other electronic parts (not shown) are mounted to a mount face 101a of the substrate 101. A shield case 102 covering the electronic parts is attached to the substrate 101.

The shield case 102 is attached to the substrate 101 by bonding portions of the shield case 102 to the mount face 101a of the substrate 101. Specifically, bonding spaces 101b are secured in the four corners of the mount face 101a of the substrate 101, and four legs 102a which serve as bonding pieces are formed in the shield case 102. The four legs 102a of the shield case 102 are respectively bonded to the bonding spaces 101b in the four corners of the substrate 101.

As described above, the conventional circuit module needs to secure the bonding spaces 101b in the mount face 101a of the substrate 101, in addition to a mount space where the electronic parts are actually mounted. This means that the substrate 101 has a large outer size and results in a difficulty in reducing the size of the circuit module.

### SUMMARY OF THE INVENTION

The present invention has been made to solve the problem, and an object of the present invention is therefore to provide a circuit module reduced in size, an electronic device that includes the circuit module, and a method of manufacturing the circuit module.

In order to achieve the above-mentioned object, a circuit module according to a first aspect of the present invention includes: a substrate which has a mount face for mounting electronic parts and side faces connected to the mount face; a shield case which has a top face and a plurality of side walls erected along a perimeter of the top face; and a bonding material for bonding the substrate and the shield case. The shield case includes legs extending from given side walls out of the plurality of side walls of the shield case to overlap with portions of the side faces of the substrate, and the portions of the side faces of the substrate are bonded to the legs of the shield case by the bonding material. The shield case includes openings formed in the given side walls of the shield case to expose overlapping portions where the portions of the side faces of the substrate overlap with the legs of the shield case.

In the first aspect, as described above, the legs extend from the given side walls out of the plurality of side walls of the shield case to overlap with the portions of the side faces of the substrate, and the portions of the side faces of the substrate are bonded to the legs of the shield case by the bonding material. Accordingly, the bonding of the substrate and the shield case is accomplished without securing bonding spaces, which are for bonding the substrate and the shield case, in the mount face of the substrate. This reduces the outer size of the substrate and, as a result, the circuit module is reduced in size.

In the first aspect, as described above, the openings are formed in the given side walls of the shield case to expose overlapping portions (portions bonded by the bonding material) where the portions of the side faces of the substrate overlap with the legs of the shield case. Accordingly, the openings of the shield case can function as holes for transmitting laser light when, for example, the bonding material used needs to be heated at the time of bonding, and the bonding material alone is irradiated with laser light for selective heating. In other words, unlike the case where a reflow oven or the like is used to heat the bonding material, heating the entire substrate can be avoided. The fear of heat damage to the electronic parts is thus reduced and the reliability is improved. Exposing the overlapping portions (the portions bonded by the bonding material) where the portions of the side faces of the substrate overlap with the legs of the shield case in the openings of the shield case also makes it easy to check how well the portions of the side faces of the substrate are bonded to the legs of the shield case.

In the circuit module according to the first aspect, it is more preferred that the bonding material be solder. This structure facilitates the bonding of the portions of the side faces of the substrate to the legs of the shield case.

In the circuit module according to the first aspect, it is preferred that the openings be formed to extend from the given side walls of the shield case to the top face of the shield case. This structure exposes more of the overlapping portions (the portions bonded by the bonding material) where the portions of the side faces of the substrate overlap with the legs of the shield case, and therefore facilitates the work of bonding the portions of the side faces of the substrate to the legs of the shield case.

This is particularly advantageous in the case where the portions of the side faces of the substrate are bonded to the legs of the shield case by irradiating the bonding material with laser light, because the bonding material can be irradiated with laser light efficiently. In other words, with the openings formed to extend from the given side walls of the shield case to the top face of the shield case, the bonding material is exposed to view from the direction of the top face of the shield case, making it easy to apply laser light to the bonding material. If the openings are formed only in the given side walls of the shield case, on the other hand, the bonding material is not exposed to view from the direction of the top face of the shield case and it is difficult to apply laser light to the bonding material.

In the circuit module according to the first aspect, it is preferred that the substrate have end through holes formed therein, and the portions of the side faces of the substrate that are bonded to the legs of the shield case constitute inner walls of the end through holes. With this structure, the portions of the side faces of the substrate (the inner walls of the end through holes) are bonded to the legs of the shield case over a larger bonding area, and the bond between the substrate and the shield case is accordingly more solid. Further, the end through holes can be used as positioning portions to avoid misalignment of the substrate and the shield case with respect to each other.

In the structure in which the end through holes are formed in the substrate, it is more preferred that the end through holes have a semi-elliptical shape. Giving the end through holes a semi-elliptical shape reduces the amount of notching into the substrate, compared to giving the end through holes a semicircular shape, which is a more common shape for end through holes. The end through holes are thus formed in the substrate without reducing the mount face of the substrate in area.

In the circuit module according to the first aspect, it is more preferred that the plurality of side walls of the shield case include a pair of first side walls which face each other, and at least the pair of first side walls of the shield case serve as the given side walls from which the legs extend and in which the openings are formed. With this structure, the shield case is bonded to the substrate evenly.

In the structure in which the plurality of side walls of the shield case include the pair of first side walls which face each other, it is preferred that the plurality of side walls of the shield case further include a pair of second side walls which face each other, and at least the pair of second side walls of the shield case have front edges which are in contact with the mount face of the substrate. With this structure, the shield case is controlled such that the top face of the shield case does not tilt, and the top face of the shield case is thus kept horizontal with respect to the mount face of the substrate.

In the circuit module according to the first aspect, it is preferred that out of inner walls of the openings of the shield case, inner walls that constitute portions of the legs be flush with the mount face of the substrate in a thickness direction of the substrate.

An electronic device according to a second aspect of the present invention includes the circuit module according to the first aspect. The electronic device structured in this way is reduced in size.

A method of manufacturing a circuit module according to a third aspect of the present invention includes: fabricating a substrate which has a mount face and side faces connected to the mount face, and then mounting electronic parts to the mount face of the substrate; fabricating a shield case which has a top face and a plurality of side walls erected along a perimeter of the top face; and bonding the substrate and the shield case by a bonding material. When fabricating the shield case, legs are extended from given side walls out of the plurality of side walls of the shield case to overlap with portions of the side faces of the substrate, and openings are formed in the given side walls of the shield case to expose overlapping portions where the portions of the side faces of the substrate overlap with the legs of the shield case. The portions of the side faces of the substrate are bonded to the legs of the shield case by the bonding material while the overlapping portions where the portions of the side faces of the substrate overlap with the legs of the shield case are exposed in the openings of the shield case.

According to the third aspect where a circuit module is manufactured in the manner described above, the bonding of the substrate and the shield case is accomplished without securing bonding spaces for bonding the substrate and the shield case in the mount face of the substrate. This reduces the outer size of the substrate and, as a result, the circuit module is reduced in size.

Another advantage of the circuit module manufacturing method according to the third aspect is that when, for example, the bonding material used needs to be heated at the time of bonding, the openings of the shield case can function as holes for transmitting laser light to irradiate the bonding material alone with laser light for selective heating. The fear of heat damage to the electronic parts is thus reduced and the reliability is improved. Exposing the overlapping portions (the portions bonded by the bonding material) where the portions of the side faces of the substrate overlap with the legs of the shield case in the openings of the shield case also makes it easy to check how well the portions of the side faces of the substrate are bonded to the legs of the shield case.

In the circuit module manufacturing method according to the third aspect, it is preferred that the bonding material be solder, and the portions of the side faces of the substrate be bonded to the legs of the shield case by the solder by heating the solder through the openings of the shield case. This structure facilitates the bonding of the portions of the side faces of the substrate to the legs of the shield case.

In this case, it is more preferred that the solder be heated by heat that is generated from laser light irradiation.

### BRIEF DESCRIPTION OF THE DRAWINGS

FIG. 1 is a side view of a circuit module according to an embodiment of the present invention.

FIG. 2 is an exploded perspective view of the circuit module according to the embodiment.

FIG. 3 is a sectional view of bonded portions of the circuit module according to the embodiment.

FIG. 4 is an enlarged view of one of the bonded portions of FIG. 3.

FIG. 5 is a sectional view of the circuit module according to the embodiment.

FIG. 6 is a diagram illustrating a method of manufacturing the circuit module according to the embodiment (diagram in which the bonded portions are irradiated with laser light).

FIG. 7 is a perspective view of a shield case of a circuit module according to a modification example of the embodiment.

FIG. 8 is a diagram of a bonded portion of a circuit module according to another modification example of the embodiment.

FIG. 9 is a perspective view of a conventional circuit module.

### DETAILED DESCRIPTION OF PREFERRED EMBODIMENT

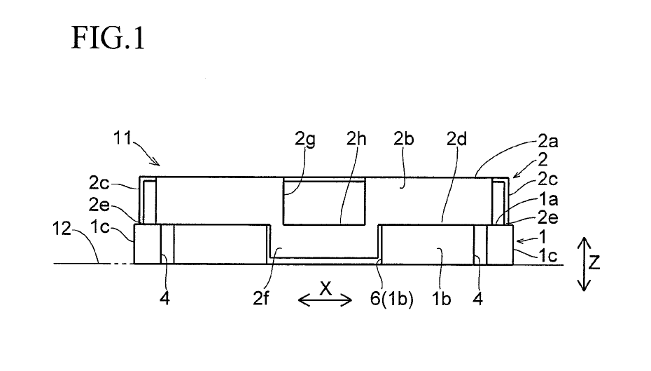

Structure of a circuit module 11 according to an embodiment of the present invention is described below with reference to FIGS. 1 to 5.

The circuit module 11 according to this embodiment is mounted to, as illustrated in FIG. 1, a motherboard 12 of a mobile device (electronic device), typically, a cell phone. The circuit module 11 includes at least a substrate 1 and a shield case 2, which is fit to the substrate 1. The substrate 1 is made from an organic substrate such as a glass-epoxy substrate, and the shield case 2 is made from a white metal sheet (sheet of an alloy containing copper, zinc, and nickel).

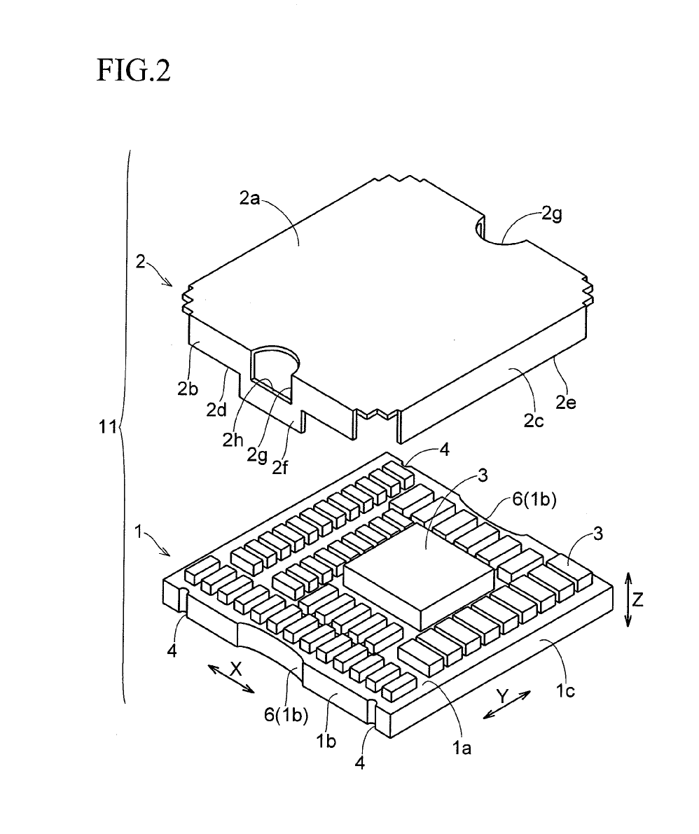

As illustrated in FIG. 2, the substrate 1 has a mount face 1a on which a metal wiring pattern (not shown) is laid out. The outer shape of the substrate 1 in plan view, in other words, the outer shape of the substrate 1 viewed from the direction of the mount face 1a, is substantially quadrangular. A plurality of electronic parts 3 are mounted to the mount face 1a of the substrate 1, and electric power (electrical signals) is supplied to the electronic parts 3 via the metal wiring pattern.

The electronic parts 3 mounted to the mount face 1a of the substrate 1 include, for example, an IC, a memory, a transistor, and a resistor, and are varied in number and type depending on the use. The electronic parts 3 may be mounted by soldering terminals of the electronic parts 3 to the metal wiring pattern, or by inserting the terminals of the electronic parts 3 in through holes and then soldering the terminals.

The substrate 1, having a substantially quadrangular outer shape in plan view, has four side faces connected to the mount face 1a. In the following description, of the four side faces of the substrate 1, a given pair of side faces of the substrate 1 which face opposite directions from each other (i.e., which face each other) is denoted by a symbol 1b, and the other pair of side faces of the substrate 1 is denoted by a symbol 1c. The following description also uses X and Y to denote directions parallel to the mount face 1a of the substrate 1, with the direction along the side faces 1b being a direction X and the direction along the side faces 1c being a direction Y, and uses Z to denote the direction of the thickness of the substrate 1 (the normal line direction of the mount face 1a).

End through holes 4 of a common type which have a semicircular shape in plan view (recesses whose inner walls are plated with metal) are formed in the side faces 1b of the substrate 1. The side faces 1c of the substrate 1, on the other hand, have no end through holes 4 formed therein. The end through holes 4 are used as external connection terminals or the like, and there are no particular limitations as to the number of the end through holes 4 and where to form the end through holes 4.

The shield case 2 is obtained by processing a white metal sheet in which the sheet is bent. The shield case 2 includes a top face 2a, which has a substantially quadrangular outer shape in plan view, and four side walls, which are erected along the perimeter of the top face 2a. When the shield case 2 is fit to the substrate 1, the mount face 1a of the substrate 1 faces the top face 2a of the shield case 2. In other words, the top side of the electronic parts 3 (the opposite side from the mount side) is covered with the top face 2a of the shield case 2. This prevents electromagnetic waves from infiltrating from the top side of the electronic parts 3, and prevents electromagnetic waves from leaking to the top side of the electronic parts 3.

With the shield case 2 fit to the substrate 1, the four side walls of the shield case 2 cover the peripheral sides of the arranged electronic parts 3. Electromagnetic waves are thus prevented from infiltrating from the peripheral sides of the arranged electronic parts 3 and are prevented from leaking to the peripheral sides of the arranged electronic parts 3. In the following description, a given pair of opposing side walls out of the four side walls of the shield case 2 is denoted by a symbol 2b, and the other pair of side walls is denoted by a symbol 2c.

The side walls 2b and 2c of the shield case 2 respectively have front edges 2d and 2e, which are flush with each other in the direction Z, except for legs 2f extended from the front edges 2d of the side walls 2b of the shield case 2 toward one side of the direction Z. No legs 2f extend from the front edges 2e of the side walls 2c. The side walls 2b and 2c of the shield case 2 are respectively an example of “first side walls” of the present invention and an example of “second side walls” of the present invention.

The shield case 2 in this embodiment is fit to the substrate 1 by bonding the legs 2f of the shield case 2 to portions of the side faces 1b of the substrate 1.

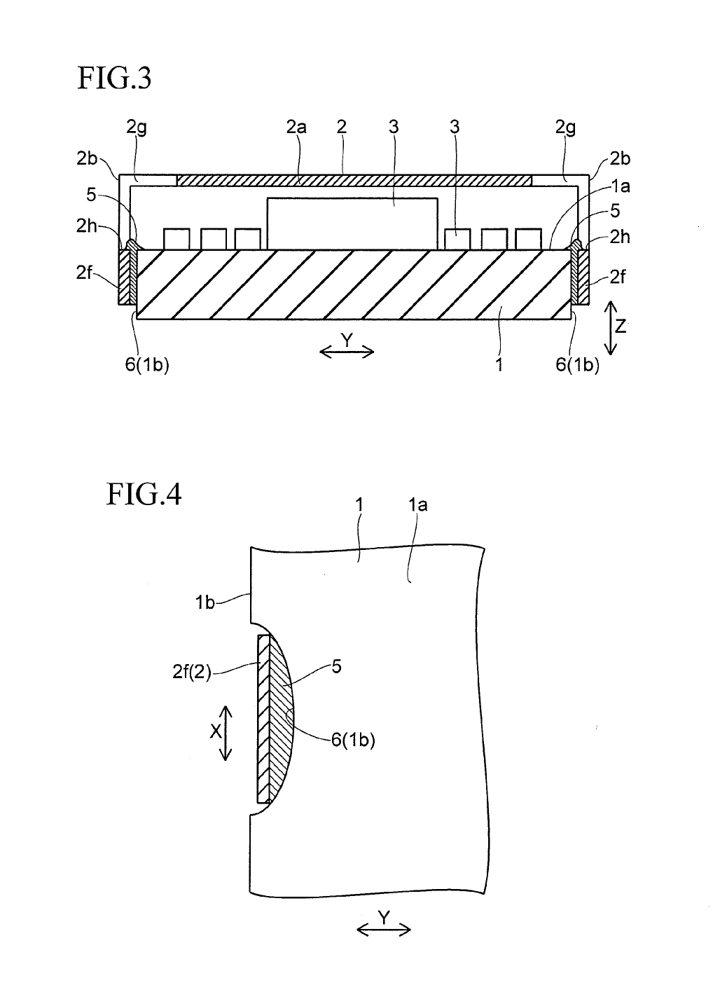

Specifically, as illustrated in FIGS. 2 and 3, each leg 2f of the shield case 2 overlaps with a portion of one of the side faces 1b of the substrate 1 (given portion between two end through holes 4). Solder 5 is provided as a bonding material on portions of the side faces 1b of the substrate 1, in other words, between portions of the side faces 1b of the substrate 1 and the legs 2f of the shield case 2. The portions of the side faces 1b of the substrate 1 are bonded to the legs 2f of the shield case 2 via the solder 5.

The width in the direction X of the legs 2f of the shield case 2 is not particularly limited. In this embodiment, each leg 2f of the shield case 2 has a width in the direction X that is set smaller than the interval between two end through holes 4 in the direction X. This is for preventing the legs 2f of the shield case 2 from electrically connecting to the end through holes 4 when the portions of the side faces 1b of the substrate 1 are bonded to the legs 2f of the shield case 2.

In this embodiment, openings 2g are formed in given portions (in the vicinity of the legs 20 of the side walls 2b of the shield case 2 to reach the top face 2a. The openings 2g of the shield case 2 expose the overlapping portions (the portions bonded by the solder 5) where the portions of the side faces 1b of the substrate 1 overlap with the legs 2f of the shield case 2. The openings 2g of the shield case 2 each have a face 2h, which is one of the inner walls of the opening 2g that constitutes a portion of one leg 2f. The face 2h is flush with the mount face 1a of the substrate 1 in the direction Z. The openings 2g of the shield case 2 are not limited to a particular shape and other shapes than the one illustrated in the drawings may be employed for the openings 2g.

With the openings 2g formed in the shield case 2 in this manner, the overlapping portions (the portions bonded by the solder 5) where the portions of the side faces 1b of the substrate 1 overlap with the legs 2f of the shield case 2 can be checked by sight from the direction of the top face 2a of the shield case 2 while the shield case 2 is fit to the substrate 1. The overlapping portions (the portions bonded by the solder 5) where the portions of the side faces 1b of the substrate 1 overlap with the legs 2f of the shield case 2 can also be checked by sight from the direction of the side walls 2b of the shield case 2 while the shield case 2 is fit to the substrate 1.

This embodiment includes, in addition to the end through holes 4, another pair of end through holes (recesses whose inner walls are plated with metal) formed in portions of the side faces 1b of the substrate 1. The additional end through holes are each denoted by 6 and formed in a given portion between two end through holes 4 as illustrated in FIGS. 2 and 4. The shape in plan view of the end through holes 6 is, instead of the semicircular shape of the end through holes 4, a semi-elliptical shape that is obtained by stretching a semicircle in the direction X. In this embodiment, the portions of the side faces 1b of the substrate 1 that are bonded to the legs 2f of the shield case 2 constitute inner walls of the end through holes 6.

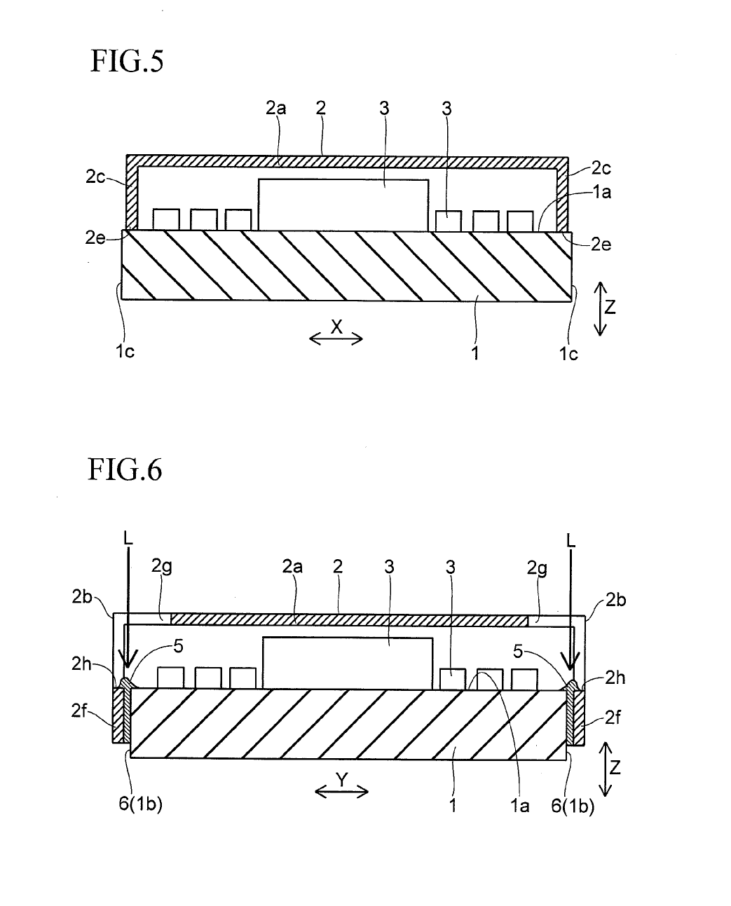

The front edges 2e of the side walls 2c of the shield case 2 in this embodiment have no legs 2f extended therefrom, but are in contact with the mount face 1a of the substrate 1 along the side faces 1c as illustrated in FIGS. 2 and 5. This keeps the distance between the mount face 1a of the substrate 1 and the top face 2a of the shield case 2 (the distance between the top face 2a of the shield case 2 and the electronic parts 3) to a desired distance.

As described above, this embodiment accomplishes the bonding of the substrate 1 and the shield case 2 to each other without securing bonding spaces, which are for bonding the substrate 1 and the shield case 2, in the mount face 1a of the substrate 1 by extending the legs 2f from the front edges 2d of the side walls 2b of the shield case 2 to overlap with portions of the side faces 1b of the substrate 1 (the inner walls of the end through holes 6), and then by bonding the portions of the side faces 1b of the substrate 1 (the inner walls of the end through holes 6) to the legs 2f of the shield case 2 with the use of the solder 5. This reduces the outer size of the substrate 1 and, as a result, the circuit module 11 is reduced in size.

In this embodiment, as described above, the openings 2g are formed in the side walls 2b of the shield case 2 to expose the overlapping portions (the portions bonded by the solder 5) where the portions of the side faces 1b of the substrate 1 (the inner walls of the end through holes 6) overlap with the legs 2f of the shield case 2. Accordingly, the openings 2g of the shield case 2 can function as laser light transmitting holes to irradiate the solder 5 alone with laser light for selective heating. In other words, unlike the case where a reflow oven or the like is used to heat the solder 5, heating the entire substrate 1 can be avoided. The fear of heat damage to the electronic parts 3 is thus reduced and the reliability is improved. Exposing the overlapping portions (the portions bonded by the solder 5) where the portions of the side faces 1b of the substrate 1 (the inner walls of the end through holes 6) overlap with the legs 2f of the shield case 2 in the openings 2g of the shield case 2 also makes it easy to check how well the portions of the side faces 1b of the substrate 1 (the inner walls of the end through holes 6) are bonded to the legs 2f of the shield case 2.

In this embodiment, as described above, the openings 2g extend from the side walls 2b of the shield case 2 to the top face 2a, and hence the overlapping portions (the portions bonded by the solder 5) where the portions of the side faces 1b of the substrate 1 (the inner walls of the end through holes 6) overlap with the legs 2f of the shield case 2 are exposed more. This facilitates the work of bonding the portions of the side faces 1b of the substrate 1 (the inner walls of the end through holes 6) to the legs 2f of the shield case 2.

This is particularly advantageous in the case where the portions of the side faces 1b of the substrate 1 (the inner walls of the end through holes 6) are bonded to the legs 2f of the shield case 2 by irradiating the solder 5 with laser light, because the solder 5 can be irradiated with laser light efficiently. In other words, with the openings 2g formed to extend from the side walls 2b of the shield case 2 to the top face 2a, the solder 5 is exposed to view from the direction of the top face 2 of the shield case 2, making it easy to apply laser light to the solder 5. If the openings 2g are formed only in the side walls 2b of the shield case 2, on the other hand, the solder 5 is not exposed to view from the direction of the top face 2a of the shield case 2 and it is difficult to apply laser light to the solder 5.

Still another advantage of this embodiment where, as described above, the legs 2f respectively extend from the pair of opposing side walls 2b of the shield case 2 and are bonded to the portions of the side faces 1b of the substrate 1 (the inner walls of the end through holes 6) is that the shield case 2 is bonded to the substrate 1 evenly.

In this embodiment, as described above, the front edges 2e of the pair of opposing side walls 2c of the shield case 2 are in contact with the mount face 1a of the substrate 1, and hence the shield case 2 is controlled such that the top face 2a of the shield case 2 does not tilt, and the top face 2a of the shield case 2 is thus kept horizontal with respect to the mount face 1a of the substrate 1. This prevents the inconvenience of an irregular increase in thickness (height) in the direction Z of the circuit module 11 in part due to the tilt of the top face 2a of the shield case 2.

In this embodiment, as described above, portions of the side faces 1b of the substrate 1 that are bonded to the legs 2f of the shield case 2 constitute the inner walls of the end through holes 6, and hence the portions of the side faces 1b of the substrate 1 (the inner walls of the end through holes 6) are bonded to the legs 2f of the shield case 2 over a larger bonding area, and the bond between the substrate 1 and the shield case 2 is accordingly more solid. Further, the end through holes 6 can be used as positioning portions to avoid misalignment of the substrate 1 and the shield case 2 with respect to each other.

In this case, giving the end through holes 6 a semi-elliptical shape reduces the amount of notching into the substrate 1, compared to giving the end through holes 6 a semicircular shape, which is a more common shape for end through holes. The end through holes 6 are thus formed in the substrate 1 without reducing the mount face 1a of the substrate 1 in area.

The circuit module 11 according to this embodiment is manufactured as follows.

First, the substrate 1 and the shield case 2 as those illustrated in FIGS. 1 and 2 are fabricated and the electronic parts 3 are mounted to the mount face 1a of the substrate 1.

Subsequently, the solder 5 in the form of cream is applied to the inner walls of the end through holes 6 of the substrate 1 as illustrated in FIGS. 3 to 5. The shield case 2 is then fit to the substrate 1 so that the top face 2a of the shield case 2 faces the mount face 1a of the substrate 1. The legs 2f extended from the front edges 2d of the side walls 2b of the shield case 2 overlap with the inner walls of the end through holes 6. The front edges 2e of the side walls 2c of the shield case 2 are brought into contact with the mount face 1a of the substrate 1. In this embodiment, with the shield case 2 fit to the substrate 1, the overlapping portions (the portions to which the solder 5 in the form of cream is applied) where the legs 2f of the shield case 2 and the inner walls of the end through holes 6 overlap with each other are exposed in the openings 2g of the shield case 2.

Next, the solder 5 in the form of cream is heated to cure the solder 5 in the form of cream. The legs 2f of the shield case 2 and the inner walls of the end through holes 6 are bonded by the solder 5 as a result.

In this step, the openings 2g of the shield case 2 in this embodiment function as holes for transmitting laser light L as illustrated in FIG. 6, thereby irradiating the solder 5 alone with the laser light L for selective heating. The openings 2g of the shield case 2 are also used as holes for checking how well the legs 2f of the shield case 2 and the inner walls of the end through holes 6 are bonded to each other after the bonding by the solder 5 is completed.

The embodiment disclosed herein is an exemplification in every respect, and should not be construed as restrictive. The scope of the present invention is defined, not by the description of the embodiment given above, but by the following scope of patent claims, and encompasses meanings equivalent to the scope of patent claims as well as all modifications within the scope of patent claims.

For instance, while the legs of the shield case are bonded to the inner walls of the end through holes formed in the substrate in the embodiment described above, the present invention is not limited thereto and the legs of the shield case may be bonded to flat portions of the side faces of the substrate. In this case, however, metallization needs to be performed on the flat portions of the side faces of the substrate in order to make solder bonding possible. This means that a metallization step is added to the manufacture process. In contrast, when the legs of the shield case are bonded to the inner walls of the end through holes formed in the substrate, the manufacture process has no additional step because the inner walls of the end through holes are plated with metal in advance.

While the legs and the openings are provided in one pair of opposing side walls out of the four side walls of the shield case in the embodiment described above, the present invention is not limited thereto and the legs and the openings may be provided in two side walls that do not face each other. Alternatively, the legs and the openings may be formed in two pairs of side walls out of the four side walls of the shield case, namely, in all of the four side walls. Other options include providing at least one leg and opening in one side wall out of the four side walls of the shield case, and providing the legs and the openings in three of the four side walls of the shield case.

The embodiment described above uses solder as a bonding material, but the present invention is not limited thereto and may employ other materials than solder as a bonding material. For example, a thermally curable resin material may be employed as a bonding material.

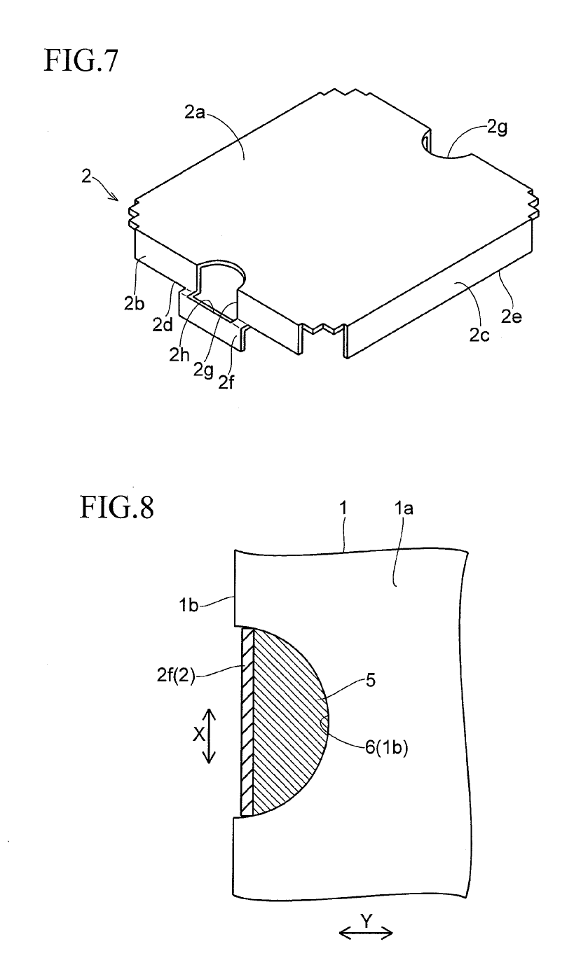

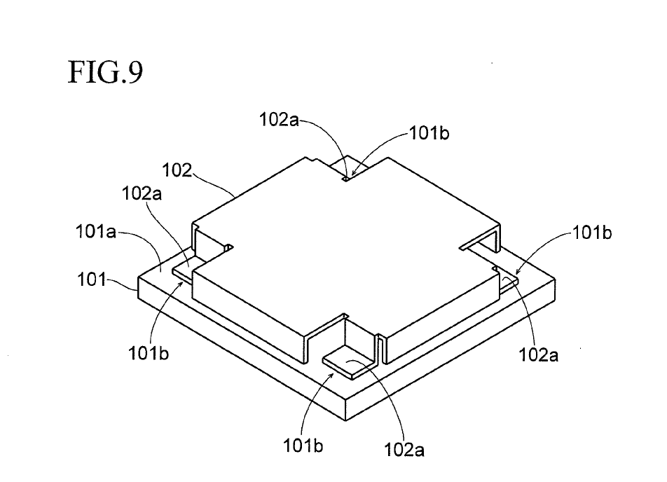

In the embodiment described above, the front edges of two of the four side walls of the shield case that are not provided with the legs and the openings are in contact with the mount face of the substrate. However, the present invention is not limited thereto and the front edges of the side walls that are provided with the legs and the openings may be in contact with the mount face of the substrate. For example, the structure of the embodiment described above may be modified as illustrated in FIG. 7, where joints between the side walls 2b and legs 2f of the shield case 2 are bent to thereby bring the front edges 2d of the side walls 2b of the shield case 2 into contact with the mount face 1a of the substrate 1 (see FIG. 2).

The legs of the shield case are bonded in the embodiment described above to the inner walls of the end through holes that have a semi-elliptical shape, but the present invention is not limited thereto and, as illustrated in FIG. 8, the legs 2f of the shield case 2 may be bonded to the inner walls of the end through holes 6 that have a semicircular shape. In this case, however, the amount of notching into the substrate 1 increases while the inner walls of the end through holes 6 and the legs 2f of the shield case 2 are bonded over a larger bonding area, which means that the mount face 1a of the substrate 1 is smaller in area.

What is claimed is:

1. A circuit module, comprising:
a substrate which has a mount face for mounting electronic parts and side faces connected to the mount face;
a shield case which has a top face and a plurality of side walls erected along a perimeter of the top face; and
a bonding material for bonding the substrate and the shield case,
wherein the shield case includes legs extending from given side walls out of the plurality of side walls of the shield case to overlap with portions of the side faces of the substrate, and the portions of the side faces of the substrate are bonded to the legs of the shield case by the bonding material, and
wherein the shield case includes openings formed in the given side walls of the shield case to expose overlapping portions where the portions of the side faces of the substrate overlap with the legs of the shield case.

2. A circuit module according to claim 1, wherein the bonding material comprises solder.

3. A circuit module according to claim 1, wherein the openings are formed to extend from the given side walls of the shield case to the top face of the shield case.

4. A circuit module according to claim 1,
wherein the substrate has end through holes formed therein, and
wherein the portions of the side faces of the substrate that are bonded to the legs of the shield case constitute inner walls of the end through holes.

5. A circuit module according to claim 4, wherein the end through holes have a semi-elliptical shape.

6. A circuit module according to claim 1,
wherein the plurality of side walls of the shield case include a pair of first side walls which face each other, and
wherein at least the pair of first side walls of the shield case serve as the given side walls from which the legs extend and in which the openings are formed.

7. A circuit module according to claim 6,
wherein the plurality of side walls of the shield case further include a pair of second side walls which face each other, and
wherein at least the pair of second side walls of the shield case have front edges which are in contact with the mount face of the substrate.

8. A circuit module according to claim 1, wherein, out of inner walls of the openings of the shield case, inner walls that constitute portions of the legs are flush with the mount face of the substrate in a thickness direction of the substrate.

9. An electronic device, comprising the circuit module of claim 1.

10. A method of manufacturing a circuit module, comprising:
fabricating a substrate which has a mount face and side faces connected to the mount face, and then mounting electronic parts to the mount face of the substrate;
fabricating a shield case which has a top face and a plurality of side walls erected along a perimeter of the top face; and
bonding the substrate and the shield case by a bonding material,
wherein, when fabricating the shield case, legs are extended from given side walls out of the plurality of side walls of the shield case to overlap with portions of the side faces of the substrate, and openings are formed in the given side walls of the shield case to expose overlapping portions where the portions of the side faces of the substrate overlap with the legs of the shield case, and
wherein the portions of the side faces of the substrate are bonded to the legs of the shield case by the bonding material while the overlapping portions where the portions of the side faces of the substrate overlap with the legs of the shield case are exposed in the openings of the shield case.

11. A method of manufacturing a circuit module according to claim 10,
wherein the bonding material comprises solder, and
wherein the portions of the side faces of the substrate are bonded to the legs of the shield case by the solder by heating the solder through the openings of the shield case.

12. A method of manufacturing a circuit module according to claim 11, wherein the solder is heated by heat that is generated from laser light irradiation.
